(19) United States
(12) Patent Application Publication
(10) Pub. No.: US 2025/0316446 A1
(43) Pub. Date: Oct. 9, 2025

(54) METHOD FOR OPERATING A PARTICLE BEAM MICROSCOPE, PARTICLE BEAM MICROSCOPE AND COMPUTER PROGRAM PRODUCT

(71) Applicant: Carl Zeiss Microscopy GmbH, Jena (DE)

(72) Inventors: Christian HENDRICH, Westhausen (DE); Rainer ARNOLD, Thalfingen (DE)

(21) Appl. No.: 19/171,905

(22) Filed: Apr. 7, 2025

(30) Foreign Application Priority Data
Apr. 9, 2024 (DE) 10 2024 109 805.8

(51) Int. Cl. H01J 37/28; H01J 37/22; H01J 37/244

(52) U.S. Cl. CPC H01J 37/28; H01J 37/222; H01J 37/226; H01J 37/244; H01J 2237/24475; H01J 2237/2448

(57) ABSTRACT

A method for operating a particle beam microscope comprises receiving a selection, by a user, of at least one detector from a plurality of detectors, wherein the selection specifies the detectors from which recorded images should be displayed. The method further comprises single or repeated scanning of an object, recording a plurality of images during a scanning procedure of single or repeated scanning using the plurality of detectors, displaying only the images recorded by the selected detectors during the single or repeated scanning procedure, storing the images recorded by the selected detectors and the images recorded by the non-selected detectors, and following the completion of the single or repeated scanning procedure, receiving a selection of at least one of the stored images recorded by one of the non-selected detectors and displaying the selected image.

### CROSS-REFERENCE TO RELATED APPLICATIONS

This application claims benefit under 35 U.S.C. § 119 to German Application No. 10 2024 109 805.8, filed Apr. 9, 2024. The entire disclosure of this application is incorporated by reference herein.

### FIELD

The present disclosure relates to a method for operating a particle beam microscope, to a particle beam microscope and to a computer program product.

### BACKGROUND

Particle beam microscopes, for example electron beam microscopes, generate a particle beam-microscopic image by virtue of an object being scanned by a particle beam of the particle beam microscope and a detector of the particle beam microscope detecting electrons and/or other secondary particles, for example photons or ions, which are emitted by the object upon incidence of the particle beam. To this end, particle beam microscopes often have several different detectors. In order to generate a particle beam-microscopic image in conventional particle beam microscopes, the user selects, from the various detectors and before the start of or during the scanning procedure, a detector that should be operated to generate the particle beam-microscopic image. Alternatively, in order to generate several particle beam-microscopic images, the user of conventional particle beam microscopes selects, from the various detectors and before the start of or during the scanning procedure, several detectors that should be operated to generate the several particle beam-microscopic images.

Once the user has selected the detector for the purpose of generating the particle beam-microscopic image and the particle beam-microscopic image was generated, the user stores the particle beam-microscopic image. They subsequently continue their work at this sample position or a different sample position or move away from the particle beam microscope in order to perform further work on the particle beam-microscopic image at their usual workstation. Should the user determine only at a later stage, for example at their workstation or at another sample position, that the particle beam-microscopic image from the utilized detector is unsuitable for the work to be performed, the user searches for the previous sample position again or puts the particle beam microscope into operation again, in order to record a new particle beam-microscopic image using one or more other detectors of the particle beam microscope; this can be laborious and time-consuming. Something similar arises in the case where the user thinks that use of a different detector of the particle beam microscope might have led to a more suitable particle beam-microscopic image. For example, it is also possible that the previous sample position is no longer suitable for recording a particle-microscopic image, for example as a result of damage to the sample position, whereupon renewed recording of this sample position using one or more other detectors is generally no longer possible.

### SUMMARY

For the aforementioned reasons, there can be limitations with conventional methods for operating particle beam microscopes, to the effect that more outlay may arise should the user retrospectively consider a recorded particle beam-microscopic image to be unsuitable.

The present disclosure seeks to avoid situations in which more outlay arises as a result of renewed putting into operation or a renewed retrieval of the sample position and a setting of the control parameters for the particle beam microscope.

According to an aspect, the disclosure provides a method for operating a particle beam microscope. The method comprises a reception of a selection, by a user of the particle beam microscope, of at least one detector from a plurality of detectors. For example, the selection can be made by virtue of the user being requested on a user interface to select one or more detectors from a predetermined list. In some embodiments, the selection by the user may be limited to exactly one detector.

The total number of selected detectors can be less than the total number of the plurality of detectors, and the selection by the user specifies the detectors from which recorded images should be displayed. Moreover, the plurality of detectors can comprise at least one detector for backscattered electrons and one detector for secondary electrons. Backscattered electrons are electrons that arise by virtue of the particles of the particle beam being scattered in such a way upon incidence on the object that the particles move away from the object. In this context, backscattered electrons have a similar energy to the impact energy of the particles upon incidence on the object. Secondary electrons are electrons that arise by virtue of electrons in the object being released by the incident particles. Secondary electrons have an energy of <50 eV and are accordingly low energy in comparison with the backscattered electrons. The detector for backscattered electrons is a detector that detects at least 1.1 times as many backscattered electrons as secondary electrons. The detector for secondary electrons is a detector that detects at least 1.1 times as many secondary electrons as backscattered electrons.

The method can further comprise single or repeated scanning of an object using a particle beam of the particle beam microscope, recording a plurality of images during a scanning procedure of single or repeated scanning of the object, wherein each image of this plurality of images is recorded by a detector of the plurality of detectors, wherein each detector of the plurality of detectors records at least one image of this plurality of images. Accordingly, each detector records particle beam-microscopic images multiple times.

The method can further comprise displaying only the images recorded by the selected detectors during the single or repeated scanning procedure and storing the images recorded by the selected detectors during the single or repeated scanning procedure and the images recorded by the non-selected detectors during the single or repeated scanning procedure. Since only the images recorded by the selected detector are displayed during the single or repeated scanning procedure, the images recorded by the non-selected detectors are not visible to the user during the single or repeated scanning procedure. For example, the images recorded by the non-selected detectors are not displayed in further windows or in any other way either. As a result, the user experience of the user of the particle beam microscope is not impaired by excessive information. For example, the user is able to use the user interface in customary fashion for the purpose of recording a particle beam-microscopic image; however, images not visible to the user are additionally recorded by the non-selected detectors. All recorded images can be stored so that the user can access these should they retrospectively determine that the recorded image from the selected detector is unsuitable for their purposes.

The method can further comprise, following the completion of the single or repeated scanning procedure, receiving a selection of at least one of the stored images recorded by one of the non-selected detectors and displaying the selected image.

Thus, as is customary, the user is able to select a detector with which a particle beam-microscopic image should be generated. The particle beam-microscopic image is then displayed during the scanning procedure. However, the particle beam microscope additionally records particle beam-microscopic images, not visible to the user, using the non-selected detectors, and these images are then stored together with the displayed images. Consequently, the user has the option of accessing images from other detectors, even after the user has moved away from the particle beam microscope or the user has performed other activities on the particle beam microscope. Therefore, the user need not put the particle beam microscope into operation again in order to re-scan the sample using one or more detectors. The aforementioned issue can be solved.

According to some embodiments, the method further comprises, following the completion of the single or repeated scanning procedure, a display of a plurality of the stored images recorded by one of the selected detectors. Further, the reception of the selection of the at least one stored image recorded by one of the non-selected detectors comprises a reception of a selection of one of the displayed images, and a use of at least one of the stored images recorded by one of the non-selected detectors, the stored image having been recorded during the same scanning procedure together with the selected displayed image, as the selected stored image recorded by the at least one of the non-selected detectors.

To put it another way, as described above, images are recorded multiple times by each detector. As a result, a recording sequence of the images is available, wherein it may be desirable to store the recorded images such that the images, following loading from a memory, can once again be assigned to one another in accordance with this recording sequence. For example, it can be desirable to store the images of a detector such that each image from this detector and each image from another detector can be assigned to one another, to be precise on the basis of which images of the detectors were recorded together during the same scanning procedure. Such an assignment enables a selection with the aid of a simplified display for the user, in which the images of the selected detector are displayed in the sequence in which they were recorded. Then, the user may select an image from the displayed image sequence and obtains an image of a non-selected detector, which was recorded together with the selected image.

According to some embodiments, the method further comprises, during the single or repeated scanning procedure, an analysis of the images recorded by the non-selected detectors during the single or repeated scanning procedure, for example by the line-by-line or image-by-image formation of a mean value or implementation of other mathematical operations, and a generation of a communication for the user on the basis of the analysis. Since the recorded images from the non-selected detectors are not visible to the user, it may be desirable to analyse these in order to communicate to the user important information identifiable in these images. To this end, it may be desirable to analyse the images of the secondary electron detector. Important information, the determination of which during the scanning procedure is usually desirable, may relate to the state of the object and the suitability of the object for high-quality particle beam-microscopic images, for example a contamination of the object or an electrical charging of the object. Should the analysis determine that electrical charging of the object has occurred, a warning specifying this may be output to the user.

According to some embodiments, the method further comprises a changing of operating parameters of the particle beam microscope, wherein the images of at least one of the selected detectors and at least one of the non-selected detectors are analyzable in order to determine a measure that represents an image quality of the images, wherein the operating parameters of the particle beam microscope are changeable such that an optimal measure for the image quality of the image recorded by the selected detector is achieved, wherein, in that case, the measure for the image quality of the image recorded by the non-selected detector is a given measure for the image quality, wherein the operating parameters of the particle beam microscope are changed in such a way that the measure for the image quality of the image recorded by the selected detector is lower than the optimal measure, and the measure for the image quality of the image recorded by the non-selected detector is better than that given measure.

For example, the measure for the image quality may represent a sharpness of the image, a contrast of the image or the like. For example, the sharpness of an image may be defined by a normalized sum of edges determined by a Sobel operator. For example, the image sharpness may be determined better by the non-selected detector than by the selected detector. In the case of the conventional methods for operating the particle beam microscope, optimal operating parameters with respect to this measure were typically determined and set for the selected detector. However, these optimal operating parameters for the selected detector frequently lead to unsatisfactory images by other detectors. Accordingly, it may be desirable to set the operating parameters of the particle beam microscope such that these deviate from the optimal operating parameters. A small deviation from the optimal operating parameters is frequently hardly identifiable in the displayed image of the selected detector; however, the images of the non-selected detectors may also be improved by a small deviation. This may increase the probability that an image of a non-selected detector is suitable retrospectively for the user.

According to some embodiments, the change in the operating parameters may be performed on the basis of the fact that the images of the at least one of the selected detectors and of the at least one of the non-selected detectors are analysed, and the measure that represents the image quality of the analysed image is determined during the single or repeated scanning procedure. According to alternative embodiments, a plurality of predetermined sets of values that represent the operating parameters of the particle beam microscope may be stored, and one of the sets of the plurality of predetermined sets of values may be selected by the user on the basis of the selection of the at least one detector. As a result, the change of the operating parameters of the particle beam microscope may be implemented on the basis of the values from the selected set of values. For example, a table may be stored in advance, with operating parameters that not only are optimal for the images of the selected detector but also offer a compromise for the image quality of the images from the non-selected detectors and the images of the selected detector being able to be determined from the table. Changing the operating parameters may also be performed in such a way that these are ascertained on the basis of changes in the operating parameters that relate to the non-selected detectors. In an alternative to that or in addition, operating parameters that relate to the non-selected detectors may also be determined on the basis of the operating parameters that relate to the selected detector. For example, corresponding dependencies may be specified in tables and/or mathematical relationships.

According to some embodiments, the plurality of detectors further comprises a radiation detector, for example an x-ray detector, and/or a detector for Auger electrons. Radiation is generated on the object, for example by emission in the event of an electron transition in atoms of the object or by bremsstrahlung. The radiation may be detected by a detector that detects at least 1.1 times as many photons as electrons. Auger electrons are electrons that are emitted on account of a further electron transition in atoms of the object. The Auger electrons have the energy characteristic for electron levels. The Auger electron detector is a detector that at least detects electrons such that the Auger electrons may be distinguished from other electrons. The plurality of detectors may also comprise a camera that records light images.

The detectors may be scintillation detectors, ionization detectors or the like, so long as the electrons or photons associated with the detector are able to be detected in a suitable manner. In this case, electrons may also be converted into photons in a gas that is situated in the surroundings of the sample or of the detector.

In the conventional methods for operating the particle beam microscope, a camera may also be selected as the detector for the purpose of visually assisting the positioning of the object, whereby the light image of the camera is displayed and no particle beam-microscopic image is recorded for as long as the camera is selected. The object is illuminated with light in order to record a light image of the camera. The method proposed here can allow for the capability of also recording particle beam-microscopic images while the light image of the camera is displayed. However, light-sensitive detectors, for example scintillation detectors for recording the particle beam-microscopic images, can be disturbed by the light should the object be illuminated with light while particle beam-microscopic images are able to be recorded.

In accordance with some embodiments, a method for operating the particle beam microscope is accordingly proposed, with which the particle beam-microscopic images may be recorded by further selected or non-selected detectors without being disturbed by the illumination of the object with light. This method for operating a particle beam microscope comprises scanning an object using a particle beam, a detection of electrons generated on the object by the particle beam using a light-sensitive detector, a generation of a particle beam-microscopic image on the basis of the detected electrons, an illumination of the object with light, and a detection of light images of the object using a camera. In this case, the generation of the particle beam-microscopic image is only based on the detected electrons that are detected during a plurality of first time intervals. The object is only illuminated in a plurality of second time intervals, wherein the first time intervals and the second time intervals overlap one another at most in part, and for example substantially do not overlap one another.

Accordingly, illuminating the object for the purpose of recording the light image by the camera is only performed when the detectors that differ from the camera do not detect any electrons relevant to the generation of the particle beam-microscopic images.

According to some embodiments, scanning the object using the particle beam comprises line-by-line scanning, in which the particle beam is scanned along a line during the first time intervals and in which the particle beam is returned to a start of a line during the second time intervals. This return is also referred to as flyback here and occurs when the particle beam is deflected from an end of one line to a start of another line. Since the incidence location of the particle beam on the object is not situated at a point on the lines relevant to the particle beam-microscopic image during a flyback time interval, results during this time interval from the detectors that differ from the camera are not taken into account in the generation of the image, which is why an illumination performed during this time interval does not disturb the generation of the particle beam-microscopic images. It may be desirable to expose the camera sensor over several flyback time intervals for each light image of the camera or perform an addition of several light images in order to obtain an improved light image.

According to some embodiments, scanning the object is performed repeatedly, wherein the particle beam is returned to a start of the scanning procedure during the second time intervals. For example, the light image of the camera is recorded while the particle beam is returned from an endpoint of the scanning procedure to a start point of the scanning procedure during a scanning procedure of the object for the purpose of generating a first particle-microscopic image and a second particle-microscopic image. This return is also referred to as frame flyback here. The time used to return the particle beam during the frame flyback may also be lengthened in order to obtain a better light image.

According to some embodiments, a particle beam microscope comprises a particle beam source for generating a particle beam, an object holder for holding an object, a deflection device for deflecting the particle beam in order to scan the object using the particle beam, a plurality of detectors and a controller configured to operate the particle beam microscope using the above-described method. According to some embodiments, the particle beam microscope comprises one or more detectors and one or more cameras.

According to some embodiments, a computer program product comprises instructions which, when executed by the controller of the particle beam microscope, cause the particle beam microscope to perform the above-described method.

Embodiments will be described in detail hereinafter with reference to the drawings. To facilitate understanding, non-selected detectors are also referred to as background detectors and selected detectors are also referred to as live detectors here. Moreover, an electron beam microscope is described in the context of the following detailed embodiments. However, it should be observed that the embodiments are also suitably applicable to other particle beam microscopes, for example ion beam microscopes.

### BRIEF DESCRIPTION OF THE DRAWINGS

FIG. 1 schematically shows an electron beam microscope.

FIG. 2 shows a flowchart with steps of a method for operating the electron beam microscope shown in FIG. 1.

FIG. 3 shows a display window of a user interface of the method shown in FIG. 2.

FIG. 4 shows a display window of a user interface of the method shown in FIG. 2.

FIG. 5 shows a flowchart with steps of a method for operating the electron beam microscope shown in FIG. 1.

FIG. 6 shows an image field of the particle beam microscope 1 shown in FIG. 1 with scanning points arranged in lines in the case of the method shown in FIG. 5.

### DETAILED DESCRIPTION

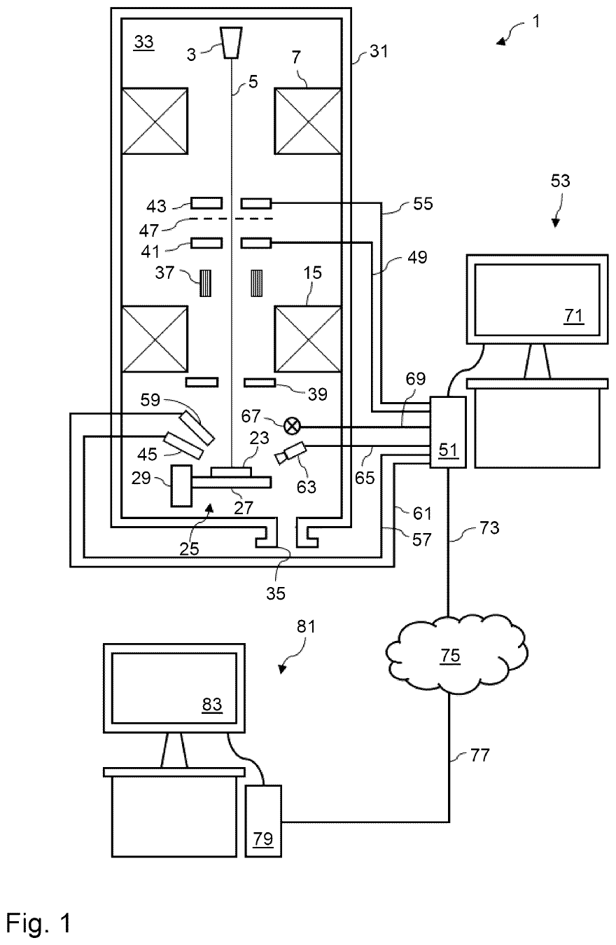

FIG. 1 schematically shows an electron beam microscope 1 according to one embodiment. The electron beam microscope 1 comprises an electron beam source 3, which generates an electron beam 5. For example, the electron beam source 3 comprises an emission cathode, not shown, from which electrons are emitted, and an acceleration anode, not shown, which accelerates the electrons and thus forms the electron beam 5.

The electron beam 5 passes through a condenser lens 7. In this case, the condenser lens 7 is a magnetic lens which has a focusing effect on the electron beam 5 by way of the generation of a magnetic field. The condenser lens 7 can be used to collimate the diverging electron beam 5 that is emitted by the electron beam source 3.

The electron beam 5 also passes through an objective lens 15. In this case, too, the objective lens 15 is a magnetic lens. The objective lens 15 can be used to focus the electron beam 5, which was collimated by the condenser lens 7, at an object 23. The condenser lens 7 and/or the objective lens 15 need not be a magnetic lens but might also be an electrostatic lens, for example.

The object 23 is held and positioned by a carrier mechanism 25, which is encompassed in the electron beam microscope 1. To this end, the carrier mechanism 25 comprises an object stage 27, which holds the object 23, and an actuator 29. The actuator 29 may be operated such that the object stage 27 is driven to different positions in the electron beam microscope 1.

The electron beam microscope 1 further comprises a vacuum cladding 31 that delimits a vacuum chamber 33. The vacuum cladding 31 comprises a pump nozzle 35, connected to which is a pump, not shown, which can be used to generate a vacuum in the vacuum chamber 33. The vacuum in the vacuum chamber 33 serves to reduce interactions between the electrons in the electron beam 5 and an atmosphere.

The electron beam 5 is deflected using a settable deflection device 37 of the electron beam microscope 1 and can thus be directed at different incidence locations on the object 23. In this embodiment, the deflection device 37 is a set of coils that generate a magnetic field in such a way that the electrons in the electron beam 5 experience a force perpendicular to the beam path of the electron beam 5 and are thus incident on the object 23 at a different incidence location. The deflection device 37 may also be formed by a set of electrodes or the like.

The deflection device 37 is used to scan the object 23 using the electron beam 5. For example, the electron beam 5 is successively directed at predetermined scanning points on the object 23. When the electron beam 5 is incident on the object 23, various effects occur on the object 23, with electrons and radiation being emitted from the object 23 on account of the effects. Secondary electrons are emitted by the object 23 when an interaction between incident electrons in the electron beam 5 and electrons present in the object 23 occurs in such a way that electrons present in the object 23 are ejected. Backscattered electrons are electrons in the electron beam 5 that interact with charged particles present in the object 23 such that the electrons from the electron beam 5 emerge from the object 23 as backscattered electrons. Auger electrons are electrons that occur when an electron transition occurs in the object 23 on account of an electron being ejected from the object 23, for example due to the generation of a secondary electron, and a further electron is ejected on account of the energy liberated in the process. Radiation occurs upon the incidence of the electron beam 5 on the object 23, for example by way of bremsstrahlung that arises in the event of a deflection of the electron in the electron beam 5, or by way of an electron transition, with the energy liberated in the process being emitted as a photon.

Electrons emitted from the object 23 may be accelerated along the beam path of the electron beam 5, at least in part by an electrostatic field that is prevalent between the object 23 and an acceleration anode 39, and may then be detected by the detectors 41 and 43. The detector 41 is a secondary electron detector that detects the low-energy secondary electrons which scatter most broadly around the electron beam 5. Low-energy secondary electrons moving in the vicinity of the electron beam 5 are repelled by an energy filter 47 and subsequently incident on the detector 41 on an upper side.

In this case, the energy filter 47 is a grid at a negative electric potential that repels electrons, wherein only the high-energy backscattered electrons are able to pass through the repulsive electrostatic field of the energy filter 47. The detector 43 is a backscattered electron detector, which detects the backscattered electrons that pass through the energy filter 47.

In this case, the detectors 41 and 43 are scintillation detectors, which generate a plurality of detectable photons due to an interaction cascade when an electron is incident. The detectable photons may then be detected by a CCD chip or a photomultiplier tube.

The Auger electrons are detected by a detector 45 that for example takes the form of an energy spectrometer. To this end, provision may be made for a detector structure which deflects electrons of different energies to different locations in a detector field by way of magnetic fields. As a result, the Auger electrons may be determined at the characteristic energies of a material of the object 23. It should be observed that the Auger electron detector 45 need not necessarily be provided as a separate detector; the Auger electrons may also be determined from a signal from another detector should this other detector be suitable for detecting an energy of the incident electrons.

It should be observed that the detectors 41, 43 and 45 do not exclusively detect secondary electrons, backscattered electrons and Auger electrons, respectively, in practice; instead, they each detect a combination of these electrons. However, the detectors 41, 43 and 45 are designed such that the detector 41 mainly detects secondary electrons, the detector 43 mainly detects backscattered electrons, and the detector 45 detects electrons in such a way that the Auger electrons may be distinguished from other electrons. For example, the ratio of secondary electrons to other electrons of the detector 41 is at least 1.1, and the ratio of backscattered electrons to other electrons of the detector 43 is at least 1.1.

The detector 41 generates an electrical signal on the basis of the detected electrons and transmits the electrical signal via a connecting line 49, which connects the detector 41 to a computer unit 51 of a control apparatus 53, to the control apparatus 53. The detector 43 generates an electrical signal on the basis of the detected electrons and transmits the electrical signal via a connecting line 55, which connects the detector 43 to the computer unit 51 of the control apparatus 53, to the control apparatus 53. The detector 45 generates an electrical signal on the basis of the detected electrons and transmits the electrical signal via a connecting line 57, which connects the detector 45 to the computer unit 51 of the control apparatus 53, to the control apparatus 53.

Although not shown in FIG. 1, the electron beam microscope 1 may comprise several detectors of the same type. For example, the electron beam microscope 1 may comprise a further secondary electron detector between the objective lens 15 and the object 23. The electron beam microscope 1 may moreover comprise a further backscattered electron detector between the objective lens 15 and the object 23. In the case of such a backscattered electron detector, it may moreover be desirable to equip the latter with several detection surfaces, which on a user interface are handled and displayed as different detectors.

The electron beam microscope 1 also comprises an x-ray detector 59, which is connected via a connecting line 61 to the computer unit 51 of the control apparatus 53. The x-ray detector 59 detects x-ray radiation that arises when the electron beam 5 is incident on the object 23. For example, the x-ray detector 59 is formed by a scintillator material and a photomultiplier tube.

The electron beam microscope 1 also comprises a camera 63, which is connected via a connecting line 65 to the computer unit 51 of the control apparatus 53. The camera records light images of the object 23 and of the carrier mechanism 25 and transmits the light images via the connecting line 65 to the control apparatus 53. In order to suitably record the light images, the electron beam microscope 1 also comprises a lamp 67, which illuminates the object 23 with light. To this end, the lamp 67 is connected via an electrical connecting line 69 to the computer unit 51 of the control apparatus 53.

The control apparatus 53 also comprises a display 71 that is connected to the computer unit 51. During the operation of the electron beam microscope 1, the display 71 displays a user interface, by which the user may provide inputs for the electron beam microscope 1 and thus perform control.

The computer unit 51 is connected via a connection 73 to a cloud 75. The cloud 75 is connected via a connection 77 to a workstation computer 79 at a workstation 81. The workstation 81 also comprises a display 83, which is connected to the workstation computer 79 and able to display a user interface. The connections 73 and 77 may be wired and wireless connections. In the event of a wired connection 73 and a wired connection 77, it may be desirable to implement a direct connection between the computer unit 51 of the electron beam microscope 1 and the workstation computer 79 and omit the cloud 75.

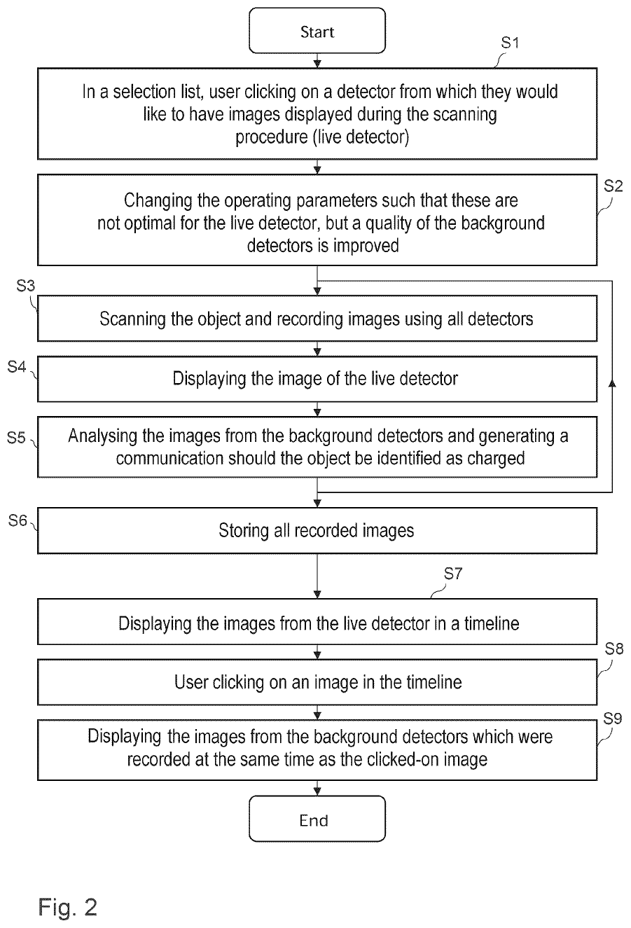

The electron beam microscope 1 is operated using a method that is described hereinafter with reference to FIG. 2. FIG. 2 shows a flowchart with steps of a method for operating the electron beam microscope 1 shown in FIG. 1 in accordance with one embodiment. The method comprises steps S1 to S9.

The operation of the electron beam microscope 1 is performed in such a way that the object 23 is scanned repeatedly, and hence particle beam-microscopic images are recorded repeatedly. This means that the user interface displayed on the display 71 displays a particle beam-microscopic image, and the latter is updated image by image with each new image recording, pixel by pixel with each scanned scanning point, line by line with each scanned line and/or block by block with scanned blocks. Accordingly, the displayed image is also referred to as live image hereinafter, and the at least one selected detector, from which the recorded images are displayed, is referred to as a live detector. Detectors, from which no images are displayed, are referred to as background detectors, and the non-displayed images of the background detectors are referred to as background images.

In step S1, the computer unit 51 receives a selection, by a user, of the detectors 41, 43, 45 and 59, with this selection specifying the detectors 41, 43, 45 and 59 from which a particle beam-microscopic image should be displayed. To this end, the user for example clicks on the secondary electron detector 41 in a list of detectors 41, 43, 45 and 59 displayed on the display by the user interface, and the secondary electron detector is subsequently registered as live detector by the computer unit 51. It should be observed that this is merely an example. In some embodiments, the user may be provided with the option of clicking several of the detectors 41, 43, 45 and 59, and so several live detectors are registered by the computer unit 51.

Then, in step S2, the operating parameters are not set such that an image quality of the live image is optimal; instead, the operating parameters are set such that the image quality of the live image is close to the optimal image quality, and an image quality of the background images is improved. For example, a measure for the image quality is a noise of the images, which may be determined using an algorithm for noise detection in the images, a contrast of the images, which may be determined from an intensity or colour histogram of the images, and/or the sharpness of the images, which may be determined using a suitable algorithm for edge detection.

Frequently, the image quality of the live image at the optimal operating parameters is so good that on the basis of a particle beam-microscopic image, a user can hardly recognize whether the operating parameters deviate slightly from the optimal operating parameters. By contrast, the optimal operating parameters are not matched to the background detectors, which is why the image quality of the background images is frequently poor. Accordingly, it can be desirable to adapt the operating parameters such that these deviate slightly from the optimal operating parameters and are thereby better matched to the background detectors. Hence, a compromise is obtained between the live image and the background images.

An example of such operating parameters of the electron beam microscope 1 are an offset and a gain of electrical signals from the detectors 41, 43, 45 and 59. For example, the gain is adapted for each of the detectors 41, 43, 45 and 59 such that the particle-microscopic image of the respective detector is optimal.

A further example for such operating parameters is a voltage of the detectors 41, 43 and 45, with which particles are drawn to a detector surface. This voltage is set for each of the detectors 41, 43 and 45 such that a compromise is obtained between the image quality of the particle-microscopic image recorded by the live detector and the image quality of the particle-microscopic images recorded by each of the background detectors. In other words, it can be desirable if the aforementioned voltage of the background detectors is not chosen to be so large that a majority of the particles are drawn to the background detectors, as a result of which only a few particles reach the live detector.

A further example for such operating parameters of the electron beam microscope 1 is a scanning speed of the electron beam microscope 1. As described hereinafter, the electron beam microscope 1 is able to scan the object 23 by virtue of the particle beam 5 being directed at a scanning point and being kept there for a predetermined dwell time. Then, after this dwell time has elapsed, the particle beam 5 is deflected from the scanning point to a next scanning point during a shorter transition time. In such a case, the scanning speed may be specified as scanning points per unit time.

An optimal scanning speed differs for different detector types. For example, a low scanning speed may cause the object 23 to experience a greater input of charge or more charging, and this causes an image recording to deteriorate. According to this example, a secondary electron detector may use a higher scanning speed than a backscattered electron detector, since the low-energy secondary electrons are influenced more by the charging of the object 23 than the high-energy backscattered electrons.

Especially in the above-described case, the scanning speed is part of a scanning strategy, which is an operating parameter of the electron beam microscope 1 and further defines at least one arrangement of the scanning points. The arrangement of the scanning points is similarly relevant to the scanning speed, as described above. Further relevant operating parameters are represented by for example a kinetic energy of the electrons in the electron beam 5 upon incidence on the object 23 and a kinetic energy of the electrons in the electron beam 5 when passing through the objective lens 15. These variables may be a voltage between the beam source 3 and the object 23 and an electric potential of a beam tube, not shown, which delimits an internal diameter of the objective lens 15.

It should be observed that step S2 is not mandatory and may be omitted in some embodiments.

The electron beam microscope 1 scans the object 23 in step S3. In this case, the electron beam microscope 1 successively directs the electron beam 5 to each of the scanning points. After the last scanning point has been reached, the electron beam microscope 1 for example starts anew at the first point, or directs the electron beam 5, for example in reverse or any desired sequence, to each of the scanning points. Consequently, the detectors 41, 43 and 45 receive electrons generated at the object 23, and the detector 59 receives radiation generated at the object 23. The detectors 41, 43, 45 and 59 generate a measurement value. The respective measurement values are transferred via the connecting lines 49, 55, 57 and 61 to the computer unit 51 and are associated with the respective scanning point, whereby a particle beam-microscopic image is generated for each detector 41, 43, 45 and 59. It should be observed that the dwell time, during which the electron beam 5 dwells at a scanning point, may be defined on an individual basis for each of the scanning points. For example, the electron beam 5 may dwell at a scanning point until the detector, which among the detectors 41, 43, 45 and 59 receives the fewest electrons or photons, has received at least a certain minimum of electrons or photons.

The display 71 shows a live image from a selected live detector. For the purpose of this description, the assumption is made that the secondary electron detector 41 was selected as live detector. The live image displayed on the display is updated in step S4 with each newly generated particle beam-microscopic image from the secondary electron detector 41. Therefore, a current particle beam-microscopic image from the secondary electron detector 41 is displayed on the display 71. The generated particle beam-microscopic images from the background detectors 43, 45 and 59 are not displayed on the display 71.

In step S5, the generated particle beam-microscopic images from the background detectors 43, 45 and 59 are analysed by the application of various algorithms in order to extract from these background images information that might already be of interest to the user of the electron beam microscope 1 while the particle beam-microscopic images are recorded. For example, such information includes whether the object 23 has been charged significantly due to irradiation by the electron beam 5 because, if significant charging of the object 23 is not identifiable in the live image or only identifiable with difficulties therewith, the user of the electron beam microscope 1 would like to be informed about such charging in order to be able to undertake appropriate adaptations to the operation of the electron beam microscope 1 and/or to the object 23. Furthermore, such an analysis may also determine whether the object 23 is contaminated.

Steps S3 to S5 are repeated any desired number of times while the user carries out work on the electron beam microscope 1, for example on the control apparatus 53 for recording the particle beam-microscopic images. When the user finishes their work on the control apparatus 53 with the user interface displayed on the display, all recorded images, i.e. the images from the live detector and the images from the background detectors, are stored in the cloud 75 or on a hard disc drive of the computer unit 51 in step S6. The recorded images may also be stored repeatedly, for example by virtue of the images generated after each generation of the particle beam-microscopic images of the detectors 41, 43, 45 and 59 being stored directly in the cloud 75. The images can be stored such that those images generated in the same scanning procedure in step S3 can be associated with one another. To this end, a recording time may be stored together with each image; however, numbering the images in a file name may already be sufficient.

Once the user has finished the work on the control apparatus 53, the user for example returns to their workstation 81. The user opens the user interface with the workstation computer 79, and the user interface is subsequently displayed on the display 83. In step S7, the user interface loads the images stored in the cloud 75 and displays the images. The loaded images can be displayed in a representation in which the user is able to identify a temporal sequence of the recording of the respective images. To this end, a timeline of the images from the live detector is initially displayed in step S7. This will be described in detail hereinafter. It should be observed that the return to the workstation 81 and the opening of the user interface with the workstation computer 79 represents an exemplary situation. The functions of the user interface described in step S7 can also be used by the user on the control apparatus 53 of the electron beam microscope 1.

In step S8, the user then clicks on one of the images from the live detector in the timeline, whereby, in step S9, images of the background detectors which were recorded together with the clicked-on image are displayed. This is possible since the images were stored such that those images generated in the same scanning procedure in step S3 can be associated with one another.

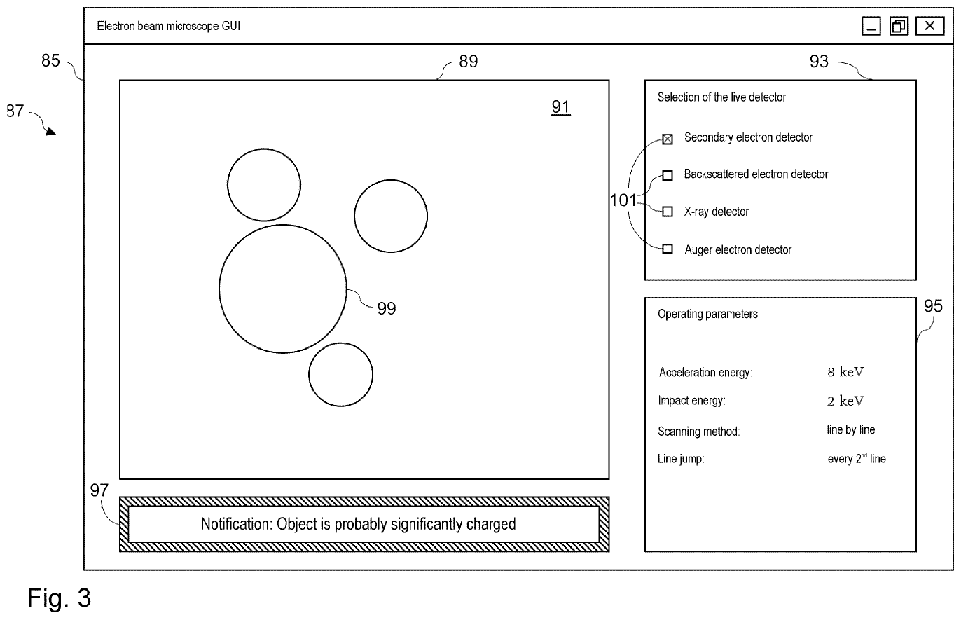

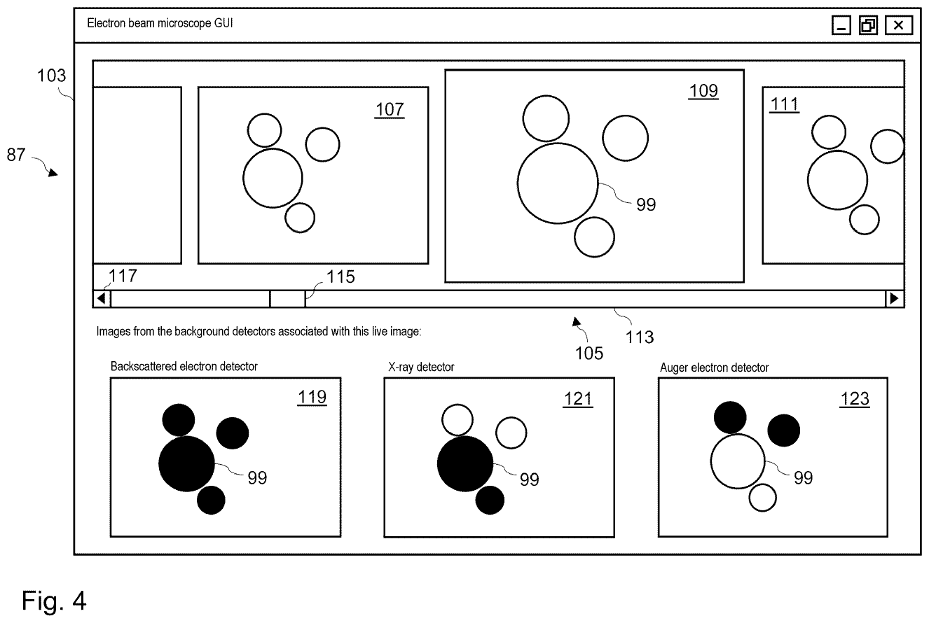

Hereinafter, the user interface displayed on the displays 71 and 83 is described with reference to FIG. 3 and FIG. 4. FIG. 3 shows a display window 85 of a user interface 87 of the method shown in FIG. 2. The display window 85 is a part of the user interface 87 that is displayed on the display 71 of the control apparatus 53.

The display window 85 comprises an image region 89 for displaying the live image 91, a selection box 93 for selecting the live detector, an information field 95 for displaying the operating parameters of the electron beam microscope 1 and a notification field 97 for displaying a communication about possible undesirable conditions when recording the images. Should an embodiment provide for a selection of several live detectors, the selection box 93 allows a selection of several live detectors, and the image region 89 may be configured such that several live images are displayed next to one another. The live image 91 shows features 99 of the object 23. The selection box comprises checkboxes 101, which are each labelled by one of the detectors 41, 43, 45 and 59. Should the user of the electron beam microscope 1 click on one of the checkboxes, the associated detector is selected as the live detector. FIG. 3 shows a case in which the secondary electron detector 41 is selected as the live detector. Accordingly, the live image 91 is an image that was generated by the secondary electron detector 41.

The information field 95 displays information about the operating parameters of the electron beam microscope 1. FIG. 3 shows a case in which the acceleration energy of the electrons in the electron beam 5, which for example is a kinetic energy-type energy of the electrons when passing through the objective lens 15, is 8 keV, the impact energy of the electrons in the electron beam 5 is 2 keV, the object 23 is scanned line by line, and the scanning strategy provides for initially every second line on the object 23 to be scanned and for the remaining lines on the object 23 to be subsequently scanned.

Should it be determined within step S5 of the method shown in FIG. 2 that the object 23 has experienced significant charging, a corresponding communication for the user of the electron beam microscope 1 is displayed in the notification field 97.

FIG. 4 shows a further display window 103 of the user interface 87 of the method shown in FIG. 2. The display window 103 comprises a timeline view 105 with several images 107, 109 and 111. The images 107, 109 and 111 show the features 99 of the object 23. The images 107, 109 and 111 can be arranged such that, in steps S3 to S5, the image 107 was recorded first, then the image 109 and thereafter the image 111, and so the sequence of the images 107, 109 and 111 from left to right corresponds to a sequence of the recording of the images 107, 109 and 111. The timeline view 105 also comprises a scrollbar 113 with a bar 115 and arrow buttons 117, by which the user can shift the timeline view 105 to a different position in the sequence of the recording of the images.

In the timeline view 105, the user can select one of the images 107, 109 and 111 by clicking on it. FIG. 4 shows a case in which the user of the electron beam microscope 1 has selected the image 109. As a result, an image 119 of the backscattered electron detector 43, an image 121 of the x-ray detector 59 and an image 123 of the Auger electron detector 45 are displayed. For example, the images 119, 121 and 123 are those that were recorded together with the selected image 109. The images 119, 121 and 123 also show the features 99 but differ from the images 107, 109 and 111; this is represented schematically by a white and black fill of the features. Accordingly, the user of the electron beam microscope 1 can easily compare the images 109, 119, 121 and 123 with one another. The user may also be able to select one of the images 119, 121 and 123, whereby this image can be displayed in an enlarged representation in a new display window.

As a result of the above-described method, the user need not necessarily put the electron beam microscope 1, for example the control apparatus 53, back into operation should the recorded images from the live detector be insufficient for their purposes. In such a case, the user may initially view images from the other detectors 43, 45 and 59, which were recorded under the same conditions and which might contain information that is used for their purposes. Accordingly, a probability is reduced that the user puts the control apparatus 53 back into operation or returns to a previous sample position again.

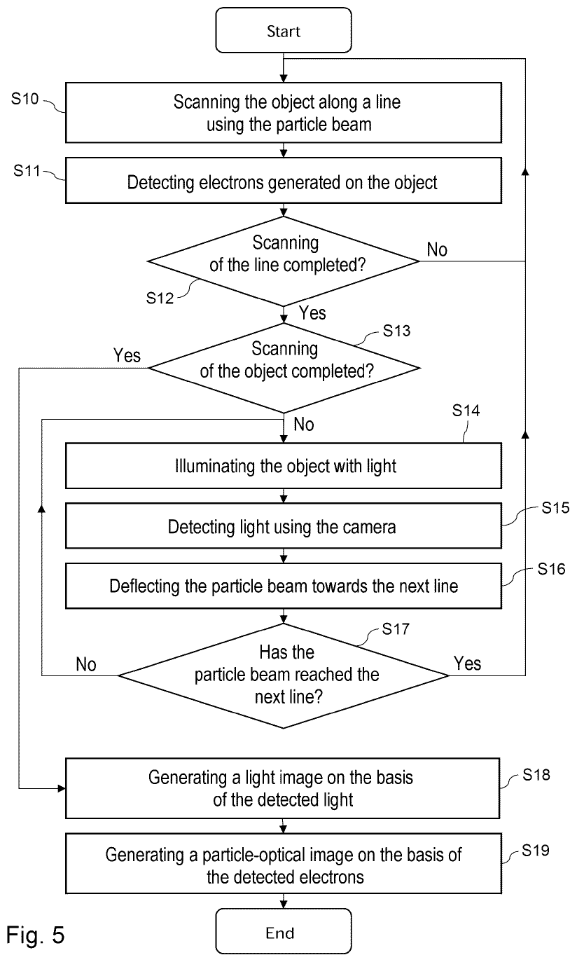

A further embodiment is described hereinafter with reference to FIG. 5. A light image from a camera is usually displayed for the purposes of positioning an object such that the object can be positioned more easily and, for example, does not collide with components of the electron beam microscope. According to the above-described method, this may for example be realized by virtue of the camera 63 being listed as a selectable detector in the selection box 93 of the user interface 87. Should the user of the electron beam microscope 1 select the camera 63 as live detector, the light image of the camera 63 is displayed in the image region 89 of the user interface 87. This also means that the detectors 41, 43, 45 and 59 continue to record images as background detectors or as live detectors selected in addition to the camera. The illumination of the object 23 with light would interfere with the recording of images by the scintillation detector if the object 23 is illuminated with light for an improved camera exposure and if at least one of the detectors 41, 43, 45 and 59 is formed as a scintillation detector.

Accordingly, an illumination of the object 23 with light is adapted in the method of the further embodiment, in such a way that the illumination of the object 23 with light does not interfere with the detectors 41, 43, 45 and 59. Accordingly, the camera 63 may alternatively also act as a background detector in the present method. FIG. 5 shows a flowchart with steps S10 to S19 of a method for operating the electron beam microscope 1 shown in FIG. 1 in accordance with the further embodiment. For example, FIG. 5 shows a generation of a light image of the camera 63 in a case in which a single detector, for example the secondary electron detector 41, records a single image.

In step S10, the object 23 is scanned along a line using the electron beam 5. In the following description, a case is assumed in which the scanning of the object 23 along the line is performed in such a way that the electron beam 5 is initially directed to a scanning point for the duration of a dwell time, subsequently deflected to a next scanning point for the duration of a shorter transition time, and thereupon directed to this scanning point anew for the duration of the dwell time.

While the object 23 is scanned, the secondary electron detector in step S1 detects secondary electrons generated at the object 23. Steps S10 and S11 are performed until there is a determination in step S12 that the scanning of the entire line on the object 23 has been completed.

Thereupon, a check is carried out in step S13 as to whether the scanning of the entire object 23 has been completed. Should the scanning of the entire object 23 be completed, the method continues with steps S18 and S19.

The object 23 is illuminated with light in step S14 should the scanning of the entire object 23 be determined as not yet completed in step S13. To this end, the lamp 67 is supplied with power by the computer unit 51. It is emphasized that this means that the object 23 is illuminated with light after scanning a line on the object 23 has been completed. In step S15, a detector field of the camera 63 is exposed by light scattered by and reflected off the object 23. During steps S14 and S15, the electron beam 5 is deflected from an end of one line to a start of the next line; this is described in step S16 of FIG. 5. The deflection of the electron beam 5 need not occur while the object 23 is illuminated with light and the scattered and reflected light is detected; instead, the electron beam microscope 1 may also suspend the deflection of the electron beam 5 from the end of the line to the start of the next line for a predetermined duration, in order to improve an exposure of the camera 63.

Should the electron beam 5 be determined to have reached the start of the next line in step S17, the electron beam microscope 1 continues with step S10 and performs the scanning of the line on the object 23 again, without illuminating the object 23 with light.

In step S18, the light image of the camera 63 is generated once the scanning of the entire object 23 has been completed. In this case, the light image from the camera 63 is only generated after the entire object 23 has been scanned since a time in which the electron beam 5 is deflected from one line to the next line is regularly too short for a suitable exposure of the detector field of the camera 63. Furthermore, the particle beam-microscopic image of the secondary electron detector 41 is generated in step S19.

Should the detection of light by the camera be performed in step S15 during a frame flyback as described above, steps S10 to S19 may be repeated for example for a plurality of particle-microscopic images. In such a case, steps S14 and S15 are then performed, additionally or alternatively, directly before step S18.

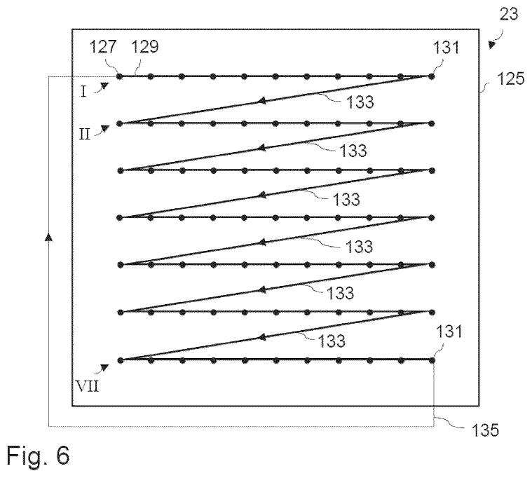

The method is vividly explained in more detail hereinafter with reference to FIG. 6. FIG. 6 shows an image field 125 of the particle beam microscope 1 shown in FIG. 1 with scanning points arranged in lines in the case of the method shown in FIG. 5. The image field 125 is scanned line by line; lines I and II have been labelled by way of example. Lines I and II each have scanning points 127 and connecting lines 129 between the scanning points 127. When scanning the line I, the electron beam 5 is directed to a scanning point 127 for the duration of the dwell time. After the dwell time has elapsed, the electron beam 5 is deflected via the adjacent connecting line 129 to the next scanning point 127 for the duration of the transition time, whereupon the electron beam 5 also remains at this scanning point 127 for the dwell time.

Once the electron beam 5 has reached the last scanning point 131 of the line I, the electron beam 5 remains at the last scanning point 131 for the duration of the dwell time and is then deflected along a flyback line to the first scanning point 127 of line II, from where the scanning is performed in a manner identical to line I. Steps S14 to S16 shown in FIG. 5 are performed while the incidence location of the electron beam 5 is on the flyback line 133. This can be since the flyback line 133 does not contain any scanning points 127, 129 and is therefore not taken into account for the generation of a particle beam-microscopic image. Accordingly, the object 23 can be illuminated with light by the lamp 67 while the incidence location of the electron beam 5 is on the flyback line 133 without this influencing the particle beam-microscopic image.

For the suitable exposure of the camera 63, it can be desirable to integrate a signal generated by the detector field of the camera 63 over several flyback lines 133, in order to prevent interference effects. With reference to FIG. 5, the light image of the camera 63 is accordingly only generated in step S18. Furthermore, the signal generated from the detector field of the camera 63 may be integrated exclusively over one or more flyback lines 133 or else additionally over connecting lines 127 and/or over scanning points 127, 131. The exposure of the camera by integrating the signal generated from the detector field of the camera 63 may be performed in any suitable manner for as long as the illumination of the object 23 with light does not influence the scintillation detectors of the electron beam system 1, for example in the embodiment shown in FIG. 6 only while the incidence location of the electron beam 5 is situated not on a scanning point 127, 131 and situated for example on a flyback line 133.

FIG. 6 also shows a frame flyback line 135 between the first scanning point 127 in line I and the last scanning point 131 in line VII. After the electron beam 5 was directed to the last scanning point 131 in line VII for the dwell time, the electron beam 5 is deflected along the frame flyback line 135 such that the electron beam 5 is guided back to the start of the scanning procedure. While the electron beam 5 is deflected along the frame flyback line 135, the object 23 can be illuminated and light can be detected by the camera 63 without interfering with light-sensitive detectors of the detectors 41, 43, 45 and 59. Since the time used for deflecting the electron beam 5 along the frame flyback line 135 is significantly longer than the time used for deflecting the electron beam 5 along the flyback lines 133, it may be possible to record a light image with the camera 63 while the electron beam 5 is deflected once along the frame flyback line 135, without using additional exposure time. Should the time not be sufficient to record a light image using the camera 63, the deflection of the electron beam 5 along the frame flyback line 135 may be slowed down or briefly halted so that a light image can be recorded with the camera 63 without additional exposure time. It should be observed that the illumination of the object 23 and the detection of light with the camera 63 during the deflection of the electron beam 5 along the frame flyback line 135 may be implemented in addition or as an alternative to the illumination of the object 23 and the detection of light with the camera 63 during the deflection of the electron beam 5 along the flyback lines 133.

It should be observed that steps S1 to S9 and steps S10 to S19 may be performed by the computer unit 51 or by the workstation computer 79, especially when these execute a computer program product that comprises instructions which, when executed by the computer unit 51 or the workstation computer 79, perform steps S1 to S9 and/or steps S10 to S19. As already described above in exemplary fashion with reference to the storing of all images in step S6, the steps may also be interchanged with one another in a suitable manner.

What is claimed is:

1. A method of operating a particle beam microscope, the method comprising:
receiving a selection, by a user of the particle beam microscope, of at least one detector from a plurality of detectors, wherein a total number of the selected detectors is less than a total number of the plurality of detectors, the selection by the user specifies the one or more detectors from which recorded images should be displayed, and the plurality of detectors comprises a backscattered electron detector and a secondary electron detector;
single or repeated scanning of an object using a particle beam of the particle beam microscope;
recording a plurality of images during a scanning procedure of single or repeated scanning of the object, wherein each image of the plurality of images is recorded by a detector of the plurality of detectors, and each detector of the plurality of detectors records at least one image of this plurality of images;
displaying the images recorded by only the selected detectors during the single or repeated scanning procedure;
storing the images recorded by the selected detectors during the single or repeated scanning procedure and the images recorded by the non-selected detectors during the single or repeated scanning procedure; and
after completing the single or repeated scanning procedure, receiving a selection of at least one of the stored images recorded by one of the non-selected detectors and displaying the selected image.

2. The method of claim 1, further comprising, after completing the single or repeated scanning procedure, displaying a plurality of the stored images recorded by one of the selected detectors, wherein receiving the selection of the at least one of the stored images recorded by one of the non-selected detectors comprises:
receiving a selection of one of the displayed images; and
using at least one of the stored images recorded by one of the non-selected detectors, the stored image having been recorded during the same scanning procedure together with the selected displayed image, as the selected stored image recorded by the at least one of the non-selected detectors.

3. The method of claim 1, further comprising:
during the single or repeated scanning procedure, analysing the images recorded by the non-selected detectors during the repeated scanning procedure; and
generating a communication for the user on the basis of the analysis.

4. The method of claim 3, wherein the analysis of the images recorded by the non-selected detectors during the single or repeated scanning procedure comprises an analysis of the images recorded by the secondary electron detector.

5. The method of claim 4, wherein an occurrence of electric charging of the object is determined on the basis of the analysis, and the communication for the user comprises a warning that electric charging of the object has occurred.

6. The method of claim 1, further comprising the change of operating parameters of the particle beam microscope, wherein:
the images of at least one of the selected detectors and at least one of the non-selected detectors are analyzable in order to determine a measure that represents an image quality of the images;
the operating parameters of the particle beam microscope are changeable such that an optimal measure for the image quality of the image recorded by the selected detector is achieved, wherein, in that case, the measure for the image quality of the image recorded by the non-selected detector is a given measure for the image quality; and
the operating parameters of the particle beam microscope are changed so that the measure for the image quality of the image recorded by the selected detector is lower than the optimal measure, and the measure for the image quality of the image recorded by the non-selected detector is better than that given measure.

7. The method of claim 6, further comprising:
analysing the images of the at least one of the selected detectors and of the at least one of the non-selected detectors; and
determining the measure that represents the image quality of the analysed image during the single or repeated scanning procedure,
wherein the change of the operating parameters of the particle beam microscope is implemented on the basis of the determined image qualities.

8. The method of claim 6, further comprising:
storing a plurality of predetermined sets of values that represent operating parameters of the particle beam microscope; and
selecting one of the sets of the plurality of predetermined sets of values on the basis of the selection of the at least one detector by the user,
wherein the change of the operating parameters of the particle beam microscope is implemented on the basis of the values from the selected set of values.

9. The method of claim 1, wherein receiving the selection from the plurality of detectors by the user is performed so that the selection comprises exactly one detector.

10. The method of claim 1, wherein the plurality of detectors further comprises a radiation detector and/or an Auger electron detector.

11. One or more machine-readable hardware storage devices comprising instructions that are executable by one or more processing devices to perform operations comprising the method of claim 1.

12. A system comprising:
one or more processing devices; and
one or more machine-readable hardware storage devices comprising instructions that are executable by the one or more processing devices to perform operations comprising the method of claim 1.

13. The system of claim 12, further comprising:
a particle beam microscope, comprising:
a particle beam source configured to generate a particle beam;
a deflection device configured to deflect the particle beam in order to scan an object using the particle beam; and
a plurality of detectors.

14. A method of operating a particle beam microscope, the method comprising:
scanning an object using a particle beam generated by the particle beam microscope;
using a light-sensitive detector to detect electrons generated at the object by the particle beam;
generating a particle beam-microscopic image on the basis of the detected electrons;
illuminating the object with light; and
detecting light images of the object using a camera,
wherein:
generating the particle beam-microscopic image is based only on the detected electrons that are detected during a plurality of first time intervals; and
illuminating the object is implemented only in a plurality of second time intervals;
the first and second time intervals at most partially overlap.

15. The method of claim 14, wherein the first and second time intervals do not substantially overlap.

16. The method of claim 14, wherein scanning the object using the particle beam comprises line-by-line scanning, in which the particle beam is scanned along a respective line during the first time intervals and in which the particle beam is returned to a start of a line during the second time intervals.

17. The method of claim 14, wherein:
scanning the object is performed repeatedly; and
during the second time intervals, the particle beam is returned to a starting point for the scanning.

18. One or more machine-readable hardware storage devices comprising instructions that are executable by one or more processing devices to perform operations comprising the method of claim 14.

19. A system comprising:
one or more processing devices; and
one or more machine-readable hardware storage devices comprising instructions that are executable by the one or more processing devices to perform operations comprising the method of claim 14.

20. The system of claim 19, further comprising:
a particle beam microscope, comprising:
a particle beam source configured to generate a particle beam;
a deflection device configured to deflect the particle beam in order to scan an object using the particle beam; and
a plurality of detectors.
